(19) United States
(12) Patent Application Publication
(10) Pub. No.: US 2025/0270684 A1
(43) Pub. Date: Aug. 28, 2025

(54) VAPOR DEPOSITION MASK AND METHOD FOR MANUFACTURING ORGANIC ELECTRONIC DEVICE

(71) Applicant: CANON KABUSHIKI KAISHA, Tokyo (JP)

(72) Inventor: YOUICHI FUKAYA, Tokyo (JP)

(21) Appl. No.: 19/063,033

(22) Filed: Feb. 25, 2025

(30) Foreign Application Priority Data
Feb. 28, 2024 (JP) 2024-028534

(51) Int. Cl. C23C 14/04; H10K 71/16

(52) U.S. Cl. CPC C23C 14/042; H10K 71/166

(57) ABSTRACT

A vapor deposition mask includes a base member made of a non-magnetic material. The base member includes a first region having a plurality of through holes and a second region thicker than the first region. The second region has a recess including a magnetic layer therein.

### BACKGROUND

### Technical Field

The present disclosure relates to a vapor deposition mask and a method for manufacturing an organic electronic device.

### Description of the Related Art

Organic electroluminescence (EL) elements are light-emitting display elements having a layered structure of thin films and capable of responding at high speed. Organic EL panels are lightweight and can constitute display devices highly capable of displaying moving images, and therefore have attracted considerable attention as display devices, such as flat-panel display (FPD) televisions or small displays for electronic viewfinders (EVFs).

Organic EL display devices are often manufactured by vapor-depositing an organic material using a vacuum vapor deposition apparatus of resistance heating type. Particularly in full-color organic EL display devices, fine red, green and blue (RGB) light-emitting elements need to be produced with high accuracy. The full-color organic EL display devices are thus manufactured with a mask vapor deposition technique in which a vapor deposition mask made of a magnetic metal or the like is used to selectively vacuum-deposit different organic materials for respective RGB pixels at desired positions. The mask vapor deposition technique is a technique with which a vivid full-color organic EL display device is manufactured by vapor-depositing materials through a vapor deposition mask that is closely attracted by a magnet or the like to a substrate to be subjected to vapor deposition.

Vapor deposition masks are often made of a magnetic material. This is because a vapor deposition mask made of a magnetic material can be closely attached, by using a magnet or the like, relatively easily to a substrate to be subjected to vapor deposition. However, such a vapor deposition mask made of a magnetic material has some drawbacks which include its heavy weight, difficulty in processing with high accuracy, and susceptibility to plastic deformation.

To reduce the weight of a vapor deposition mask, Japanese Patent Laid-Open No. 2017-20068 discloses a technique in which a resin mask has recesses or through holes that are provided with a magnetic member therein. With this technique, it is possible to reduce the weight of the mask and improve adhesion between the vapor deposition mask and a substrate to be subjected to vapor deposition.

Japanese Patent Laid-Open No. 2001-185350 proposes a technique in which a vapor deposition mask is manufactured using a silicon substrate as a base material that can be processed with high accuracy and is resistant to plastic deformation. Since silicon can be processed using a semiconductor manufacturing technique, processing accuracy can be improved to several micrometers.

Organic EL display devices have become increasingly high-definition in recent years. Thus, since high-precision processing is required, a vapor deposition mask is extremely thin. This creates a challenge in attracting the vapor deposition mask with magnetic force.

In the vapor deposition mask described in Japanese Patent Laid-Open No. 2017-20068, a thinner resin mask means shallower recesses or through holes and this means, as a result, that a magnetic material applied is also thinner. Thus, the volume of the magnetic material decreases, and it is difficult to obtain a magnetic force that is large enough to bring the vapor deposition mask into contact with a substrate to be subjected to vapor deposition.

Another challenge created when the vapor deposition mask is thinner is that the vapor deposition mask is prone to plastic deformation or damage. Even if a thinner region of the vapor deposition mask can be reliably attracted by magnetic force, the region made of, for example, resin or metal may be plastically deformed by stress applied thereto. If the thinner region is constituted by a silicon substrate, as described in Japanese Patent Laid-Open No. 2001-185350, the thinner region may be too fragile to withstand the magnetic force and may be damaged.

### SUMMARY

A vapor deposition mask according to an aspect of the present disclosure includes a base member made of a non-magnetic material. The base member includes a first region having a plurality of through holes and a second region thicker than the first region. The second region has a recess including a magnetic layer therein.

Further features of the present disclosure will become apparent from the following description of exemplary embodiments with reference to the attached drawings.

### BRIEF DESCRIPTION OF THE DRAWINGS

FIG. 1A and FIG. 1B schematically illustrate a vapor deposition mask according to a first embodiment.

FIG. 2 is a schematic cross-sectional view illustrating how vapor deposition is performed using the vapor deposition mask illustrated in FIG. 1A and FIG. 1B.

FIG. 3A and FIG. 3B are schematic cross-sectional views each illustrating a comparative example of the present disclosure.

FIG. 4A to FIG. 4D are schematic cross-sectional views illustrating an example of a method for manufacturing the vapor deposition mask according to the first embodiment.

FIG. 5A to FIG. 5C are schematic cross-sectional views illustrating the example of the method for manufacturing the vapor deposition mask according to the first embodiment.

FIG. 6 is a schematic cross-sectional view illustrating how vapor deposition is performed using a vapor deposition mask according to a second embodiment.

FIG. 7A to FIG. 7D are schematic cross-sectional views illustrating an example of a method for manufacturing the vapor deposition mask according to the second embodiment.

FIG. 8 is a schematic cross-sectional view illustrating how vapor deposition is performed using a vapor deposition mask according to a third embodiment.

FIG. 9A to FIG. 9D are schematic cross-sectional views illustrating an example of a method for manufacturing the vapor deposition mask according to the third embodiment.

FIG. 10 schematically illustrates an example of a display device according to an embodiment of the present disclosure.

FIG. 11A schematically illustrates an example of an imaging device according to an embodiment of the present disclosure, and FIG. 11B schematically illustrates an example of an electronic apparatus according to an embodiment of the present disclosure.

FIG. 12A schematically illustrates an example of a display device according to an embodiment of the present disclosure, and FIG. 12B schematically illustrates an example of a foldable display device according to an embodiment of the present disclosure.

FIG. 13A schematically illustrates an example of an illuminating apparatus according to an embodiment of the present disclosure, and FIG. 13B schematically illustrates an example of a moving body including a vehicle lighting tool according to an embodiment of the present disclosure.

FIG. 14A schematically illustrates an example of a wearable device according to an embodiment of the present disclosure, and FIG. 14B schematically illustrates another example of the wearable device according to the embodiment of the present disclosure.

FIG. 15A schematically illustrates an example of an image forming apparatus according to an embodiment of the present disclosure, and FIG. 15B and FIG. 15C each schematically illustrate an example of an exposing source of the image forming apparatus according to the embodiment of the present disclosure.

### DESCRIPTION OF THE EMBODIMENTS

Embodiments of the present disclosure will now be described with reference to the drawings. Note that the present disclosure can be implemented in many different forms, and is not to be interpreted as being limited to the description of the embodiments set forth herein. For more clarification of the description, the widths, thicknesses, shapes, and the like of components of actual embodiments may be schematically illustrated in the drawings. However, they are merely examples and are not to limit the interpretation of the present disclosure.

### First Embodiment

A first embodiment of the present disclosure will now be described.

### Vapor Deposition Mask

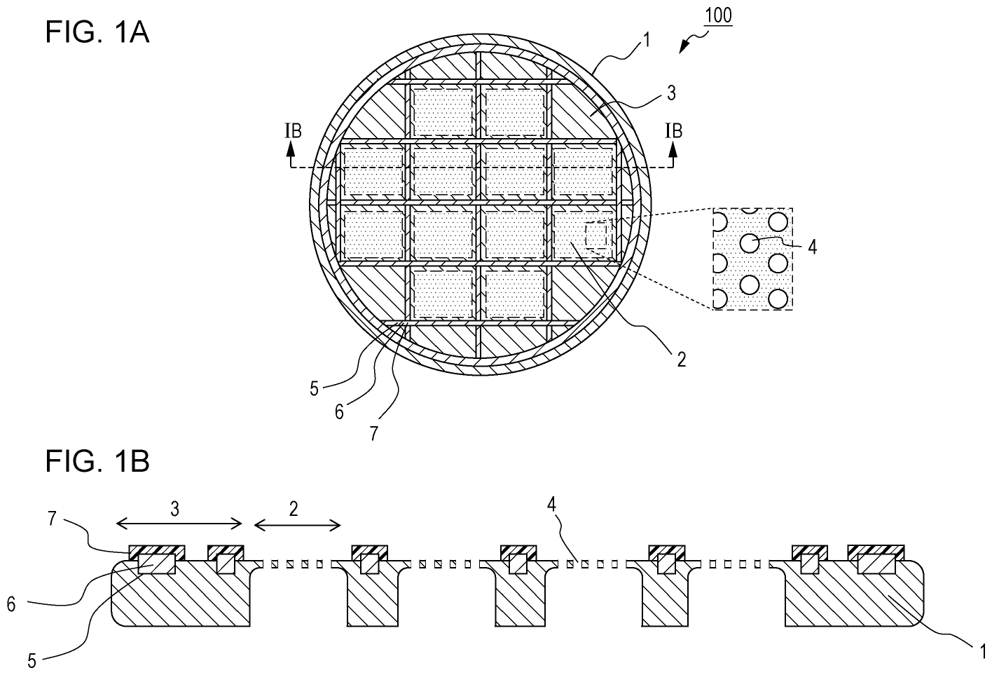

FIG. 1A and FIG. 1B schematically illustrate a vapor deposition mask according to the first embodiment of the present disclosure. FIG. 1A is a schematic plan view as seen from a surface facing a substrate to be subjected to vapor deposition. FIG. 1B is a schematic view of a cross-section taken along line IB-IB in FIG. 1A.

A vapor deposition mask 100 illustrated in FIG. 1A and FIG. 1B includes a base member 1 made of a non-magnetic material. As illustrated in FIG. 1B, the base member 1 includes a membrane region (first region) 2 having a plurality of openings (through holes) 4 and a beam region (second region) 3 thicker than the membrane region 2. The membrane region 2 is disposed to be flush with a surface of the beam region 3 having a magnetic layer 6 therein. As illustrated in FIG. 1A, the base member 1 is circular and includes a plurality of rectangular membrane regions 2. The beam region 3 is disposed around the membrane regions 2 and at an end portion of the base member 1. The beam region 3 has a recess 5 in the form of a grid-like groove and also in the form of an annular groove along the outer periphery of the base member 1. The depth of the recess 5 is greater than the thickness of the membrane regions 2. The magnetic layer 6 is embedded in the recess 5. The thickness of the magnetic layer 6 is greater than the depth of the recess 5. A low-hardness layer 7 is disposed on the surface of the magnetic layer 6.

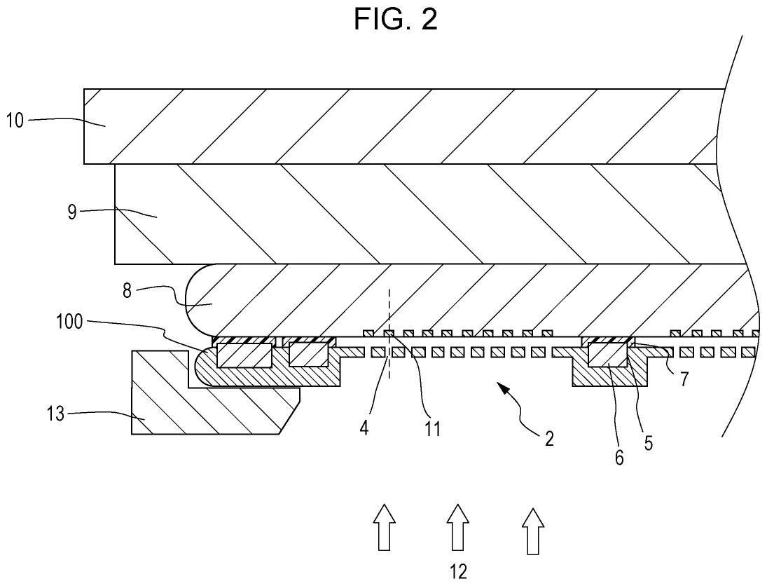

FIG. 2 is a schematic cross-sectional view illustrating how vapor deposition is performed using the vapor deposition mask illustrated in FIG. 1A and FIG. 1B. As illustrated in FIG. 2, a substrate to be subjected to vapor deposition (hereinafter simply referred to as substrate) 8 is held by an electrostatic chuck 9, with a surface to be subjected to vapor deposition facing downward. A magnet 10 is disposed on a surface of the electrostatic chuck 9 opposite a surface thereof adjacent to the substrate 8. The vapor deposition mask 100 is disposed such that a surface thereof having the magnetic layer 6 therein faces the substrate 8. At least part of an end portion of the vapor deposition mask 100 is held by a mask holder 13 made of a magnetic material. The magnet 10 attracts the mask holder 13 and the magnetic layer 6 of the vapor deposition mask 100, so as to bring the low-hardness layer 7 of the vapor deposition mask 100 into contact with the substrate 8. The vapor deposition mask 100 is aligned such that the openings 4 face respective areas to be subjected to vapor deposition (hereinafter simply referred to as areas) 11 of the substrate 8. A vapor deposition material flying from a vapor deposition source 12 (not illustrated) disposed below the vapor deposition mask 100 passes through the openings 4 and adheres to the areas 11.

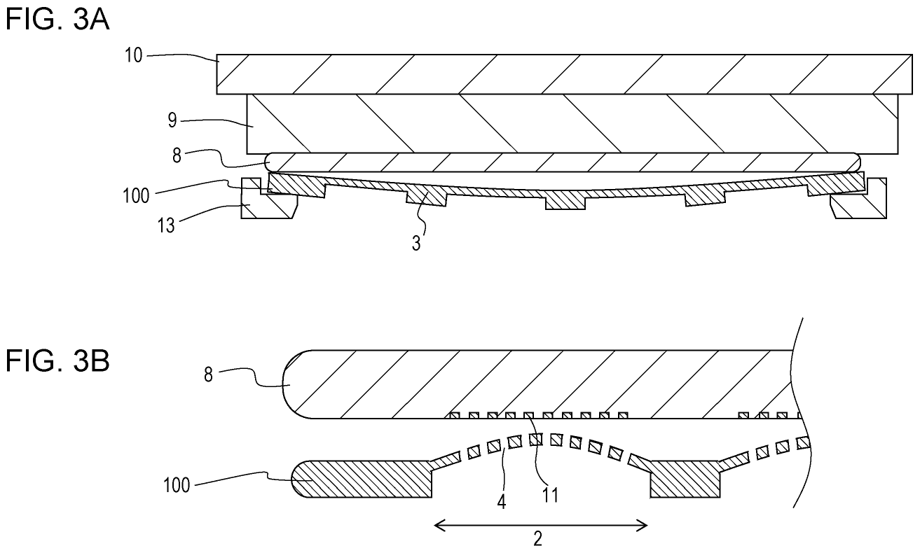

Advantageous effects of the present embodiment will now be described in comparison with comparative examples illustrated in FIG. 3A and FIG. 3B.

A main function of the magnetic layer 6 according to the present embodiment is to hold the vapor deposition mask 100 as parallel as possible to the substrate 8. For comparison, FIG. 3A illustrates an example of how the vapor deposition mask 100 and the substrate 8 face each other in the absence of the magnetic layer 6 in the present embodiment. Note that the illustration of the openings 4 and the areas 11 is omitted in FIG. 3A. In the example illustrated in FIG. 3A, the vapor deposition mask 100 warps due to its own weight or stress, and cannot be held parallel to the substrate 8. In the present embodiment, on the other hand, the beam region 3 disposed inside and on the outer periphery of the vapor deposition mask 100 is provided with the magnetic layer 6. Therefore, even when the vapor deposition mask 100 warps as illustrated in FIG. 3A, the magnet 10 can attract the magnetic layer 6, so that the vapor deposition mask 100 can be disposed parallel to the substrate 8.

To bring the low-hardness layer 7 of the vapor deposition mask 100 into contact with the substrate 8, a magnetic force exceeding the weight of the vapor deposition mask 100 may be generated between the magnetic layer 6 and the magnet 10. The volume of the magnetic layer 6 may be increased to generate a large magnetic force. In the present embodiment, however, the thickness of the magnetic layer 6 is set thicker than the membrane regions 2 and the recess 5, so that a sufficient volume can be secured.

In the present embodiment, the base member 1 is made of a non-magnetic material and the membrane regions 2 do not include the magnetic layer 6. This is to prevent plastic deformation of or damage to the membrane regions 2 when the magnet 10 attracts the vapor deposition mask 100. For comparison, FIG. 3B illustrates an example of how the vapor deposition mask 100 and the substrate 8 face each other when the membrane regions 2 are made of a magnetic material. Note that the illustration of the electrostatic chuck 9, the magnet 10, and the mask holder 13 is omitted in FIG. 3B. The membrane regions 2 are generally very thin and easily deformed when subjected to external force. That is, when the magnet 10 attracts the vapor deposition mask 100, the membrane regions 2 each significantly bulge in the center thereof toward the substrate 8 in the example illustrated in FIG. 3B and are prone to plastic deformation or damage. In the present embodiment, on the other hand, the membrane regions 2 do not contain a magnetic material and are made only of a non-magnetic material. Therefore, the membrane regions 2 are not deformed by magnetic force and the risk of plastic deformation or damage can be reduced.

In the present embodiment, the magnetic layer 6 and the low-hardness layer 7 also serve as a spacer, so that the membrane regions 2 are not in contact with the substrate 8. This can further reduce the risk of damage to the membrane regions 2 caused by contact with the substrate 8.

Each component of the vapor deposition mask 100 according to the present embodiment will now be described.

### Membrane Region (First Region) 2

The membrane regions 2 can be held as flat as possible to the substrate 8. For this, the membrane regions 2 can be made of a non-magnetic material with a volume magnetic susceptibility of 1 or less, so as to prevent deformation caused by the magnetic field of the magnet 10. A material selected to form the membrane regions 2 can be a high rigidity material that is resistant to deformation and has a Young's modulus of greater than or equal to 50 GPa, preferably greater than 100 GPa. When the membrane regions 2 have a film structure that exerts tensile stress as a whole, it is easier to maintain a flat state of the membrane regions 2. For the openings 4 to be arranged with high accuracy and precision, it is even better to select the material for the membrane regions 2 by also taking into consideration the ease of processing. The membrane regions 2 may be formed by using a base material, such as a semiconductor substrate, as it is, or by using chemical vapor deposition (CVD), sputtering, or any of various plating methods.

The Young's modulus of a main layer of each membrane region 2 is preferably greater than or equal to 50 GPa, more preferably greater than or equal to 100 GPa, and still more preferably greater than 100 GPa. The main layer of the membrane region 2 can be a non-magnetic metal layer. The main layer of the membrane region 2 can contain silicon (Si). Note that the main layer of the membrane region 2 here is the thickest layer of all layers constituting the membrane regions 2. When there are a plurality of layers made of the same material, the total thickness of the layers made of the same material is the thickness of the layer made of that material. Here, a main layer of a member can be a layer of which thickness is the greatest among layers included in the member.

### Beam Region (Second Region) 3

The beam region 3 is a component that determines the rigidity and mass of the entire vapor deposition mask 100. Therefore, the beam region 3 can be made of a material that has not only a rigidity same as or similar to that of the membrane regions 2, but also a specific gravity lighter than that of the membrane regions 2. Further, if a material having a small coefficient of linear expansion or a material having a coefficient of linear expansion close to that of the substrate 8 to be adhered is used, alignment deviation due to heat generation between the mask 100 and the substrate 8 to be adhered can be suppressed. The beam region 3 may be formed by using a base material, such as a semiconductor substrate, as it is, or by using CVD, sputtering, or any of various plating methods.

### Magnetic Layer 6

The magnetic layer 6 can be made of a material that is easily attracted to the magnet 10. A material selected to form the magnetic layer 6 thus preferably has a volume magnetic susceptibility of greater than or equal to 10, and more preferably has a volume magnetic susceptibility of greater than or equal to 100. Examples of the selectable material include iron, nickel, cobalt, and alloys of these metals. The magnetic layer 6 may be formed by electroplating or electroless plating, or by any of various printing methods, such as screen printing or patterning with a dispenser using an ink made of a magnetic material.

### Low-Hardness Layer 7

The low-hardness layer 7 is a component that is in direct contact with the substrate 8. Therefore, the low-hardness layer 7 is required not to damage the substrate 8. A material selected to form the low-hardness layer 7 can thus be a material having a lower hardness than those forming the base member 1 and the magnetic layer 6. The low-hardness layer 7 can have a lower hardness than the surface of the magnetic layer 6 and the surface of the membrane regions 2 on the same side as the surface of the beam region 3 having the magnetic layer 6 therein. The low-hardness layer 7 can be made of an organic material, or can contain fluororesin. The low-hardness layer 7 may be formed by using any of various vapor deposition techniques, CVD, sputtering, or any of various plating methods.

### Method for Manufacturing Vapor Deposition Mask

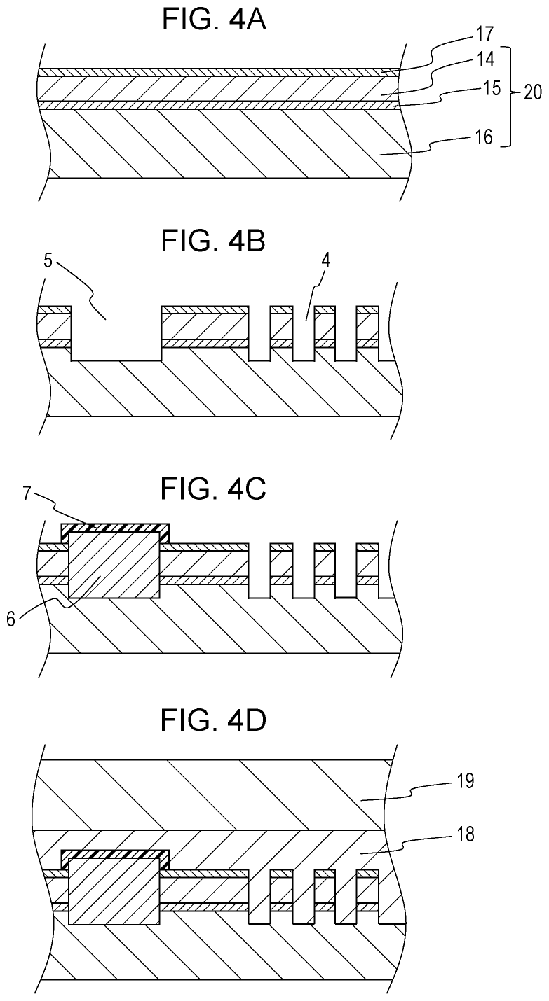

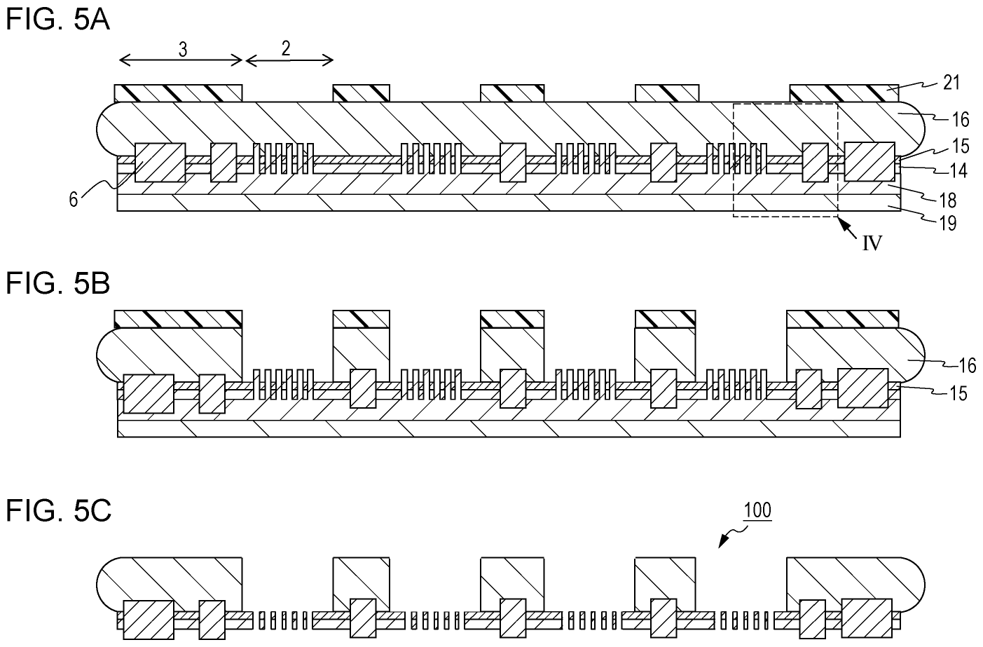

An example of a method for manufacturing the vapor deposition mask according to the present embodiment will now be described using FIG. 4A to FIG. 4D and FIG. 5A to FIG. 5C. Note that FIG. 4A to FIG. 4D illustrate part IV of FIG. 5A upside down. In FIG. 5A to FIG. 5C, the illustration of a stress adjusting layer 17 and the low-hardness layer 7 is omitted.

A silicon on insulator (SOI) substrate 20 is used as a base material. In the present example, a device layer 14 of the SOI substrate 20 is a main layer of each membrane region 2. Therefore, the thickness of the device layer 14 is set thicker than a buried oxide (BOX) layer 15. The device layer 14 is a layer of single crystal silicon, which is high in Young's modulus, light in specific gravity, finely patterned easily, and thus is suitable as a material for forming the membrane region 2.

First, as illustrated in FIG. 4A, the stress adjusting layer 17, such as a SiN film, is formed on the surface of the device layer 14 of the SOI substrate 20 by plasma-enhanced CVD or the like to a thickness thinner than the device layer 14. The stress adjusting layer 17 is a surface layer of the membrane region 2 on the same side as the surface of the beam region 3 having the magnetic layer 6 therein. Under tensile stress applied by the stress adjusting layer 17, the membrane region 2 to be formed later can be easily maintained in a flat state.

Next, as illustrated in FIG. 4B, the recess 5 and regions to be turned into the openings 4 are patterned by photolithography. In the present example, not only the stress adjusting layer 17 and the device layer 14, but also the BOX layer 15 and part of a handle layer 16, are etched, for example, by reactive ion etching (RIE) using a reactive gas.

After forming of a seed layer (not illustrated) in the recess 5, the magnetic layer 6 made of magnetic metal, such as nickel, is formed, as illustrated in FIG. 4C, to a thickness greater than the depth of the recess 5 by electroplating or the like. Then, for example, electroless nickel and polytetrafluoroethylene (PTFE) composite plating is performed on the magnetic layer 6 to form the low-hardness layer 7.

Next, as illustrated in FIG. 4D, a resist is, for example, air-sprayed over the entire surface of the SOI substrate 20 on the side of the device layer 14 to form a protective layer 18. Then, a conductive tape 19 is attached onto the top of the protective layer 18 for more protection.

Next, the SOI substrate 20 to which the conductive tape 19 has been applied is subjected to processing on the side of the handle layer 16. First, as illustrated in FIG. 5A, a pattern of the resist 21 is formed, in a region to be turned into the beam region 3, by photolithography on the surface of the handle layer 16. Note that openings in the resist 21 become the membrane regions 2.

Next, as illustrated in FIG. 5B, the handle layer 16 is etched to the BOX layer 15. For example, the Bosch process can be used for etching.

Next, as illustrated in FIG. 5C, the conductive tape 19 is removed from the SOI substrate 20, and the resist 21 and the protective layer 18 are peeled off with an organic solvent to obtain the vapor deposition mask 100.

The vapor deposition mask of the first embodiment obtained as described above is a fine mask, as it is processed using a silicon process. Also, the vapor deposition mask of the first embodiment can be reliably attracted to the magnet and is resistant to plastic deformation and damage when attracted to the magnet or when brought into contact with the substrate to be subjected to vapor deposition. It is thus possible to achieve high precision and improved reliability of an organic electronic device, such as an organic light-emitting device.

A vapor deposition mask can thus be provided, which is resistant to plastic deformation and damage and can be reliably attracted by magnetic force.

### Second Embodiment

### Vapor Deposition Mask

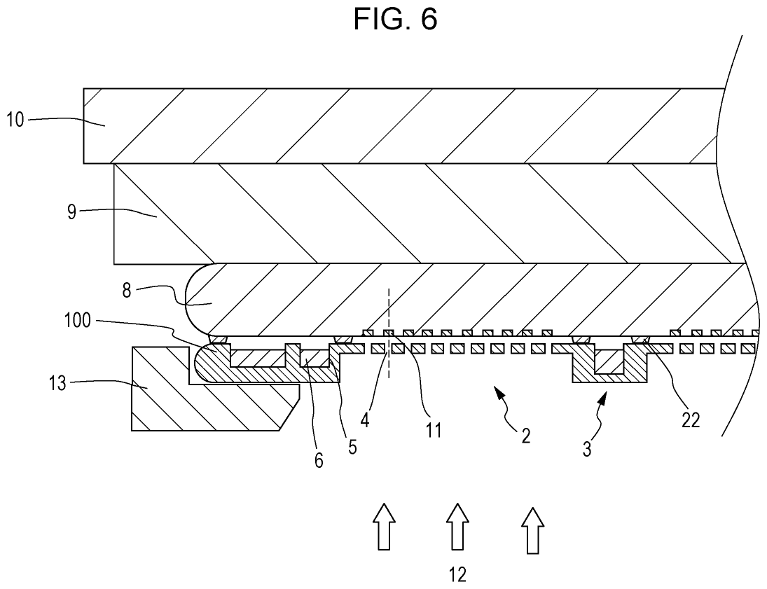

FIG. 6 is a schematic cross-sectional view illustrating how vapor deposition is performed using a vapor deposition mask according to a second embodiment. In the present embodiment, the thickness of the magnetic layer 6 embedded in the recess 5 is less than the depth of the recess 5. The low-hardness layer 7 is absent in the present embodiment. The description of other parts will be omitted, as they are the same as or similar to the first embodiment.

The thickness of the magnetic layer 6 is less than the depth of the recess 5, but is large enough because the depth of the recess 5 is substantially greater than the thickness of the membrane region 2. Therefore, the magnetic layer 6 has a volume large enough for the magnetic layer 6 to be attracted to the magnet 10.

In the present embodiment, the magnetic layer 6 does not serve as a spacer between the vapor deposition mask 100 and the substrate 8. However, such a system is useful particularly when the substrate 8 has spacers 22 thereon, as illustrated in FIG. 6. The spacers 22 can be formed on the substrate 8 with high accuracy and precision by combining spin coating or CVD with a photolithography process. With the spacers 22, a gap between the membrane regions 2 and the substrate 8 can be narrowed and defined with high precision, so that the thickness distribution of a film to be vapor-deposited in the areas 11 can be made uniform. In such a system, the thickness of the magnetic layer 6 can be made thinner than the recess 5, so as to allow the spacers 22 to define the gap with high accuracy.

### Method for Manufacturing Vapor Deposition Mask

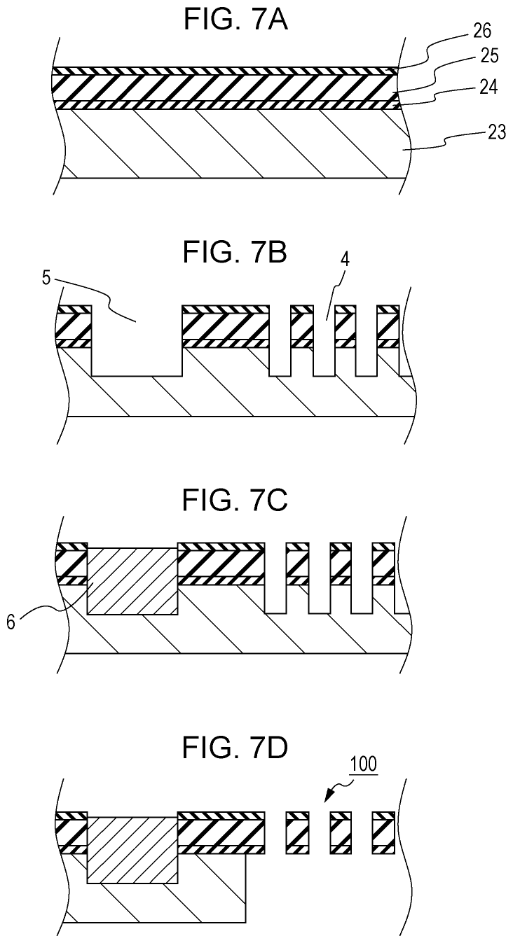

An example of a method for manufacturing the vapor deposition mask according to the present embodiment will now be described using FIG. 7A to FIG. 7D.

A silicon wafer 23 is used as a base material. First, as illustrated in FIG. 7A, a silicon oxide film 24, a silicon nitride film 25, and a silicon oxide film 26 are formed in sequence on the surface of the silicon wafer 23. For example, the silicon oxide films 24 and 26 can be formed by plasma-enhanced CVD, and the silicon nitride film 25 can be formed by low-pressure (LP)-CVD. In the present example, the silicon nitride film 25 becomes a main layer of the membrane region 2. Therefore, the thickness of the silicon nitride film 25 is set thicker than the total thickness of the silicon oxide films 24 and 26.

Next, as illustrated in FIG. 7B, the recess 5 and regions to be turned into the openings 4 are patterned by photolithography. The silicon oxide films 24 and 26 and the silicon nitride film 25 can be etched, for example, by reactive ion etching (RIE) using a reactive gas. Then, the silicon wafer 23 at the bottom of the openings 4 and the recess 5 is etched, for example, by the Bosch process.

After forming of a seed layer (not illustrated) in the recess 5, the magnetic layer 6 made of magnetic metal, such as nickel, is formed, as illustrated in FIG. 7C, to a thickness less than the depth of the recess 5 by electroplating or the like.

Then, the back side of the silicon wafer 23 is processed in a procedure similar to that illustrated in FIG. 4D to FIG. 5C of the first embodiment, so that the vapor deposition mask 100 illustrated in FIG. 7D can be obtained.

The vapor deposition mask of the second embodiment obtained as described above is a high definition mask, as it is processed using a silicon process. Also, the vapor deposition mask of the second embodiment can be reliably attracted to the magnet and is resistant to plastic deformation and damage when attracted to the magnet or when brought into contact with the substrate to be subjected to vapor deposition. It is thus possible to achieve high precision and improved reliability of an organic electronic device, such as an organic light-emitting device.

### Third Embodiment

### Vapor Deposition Mask

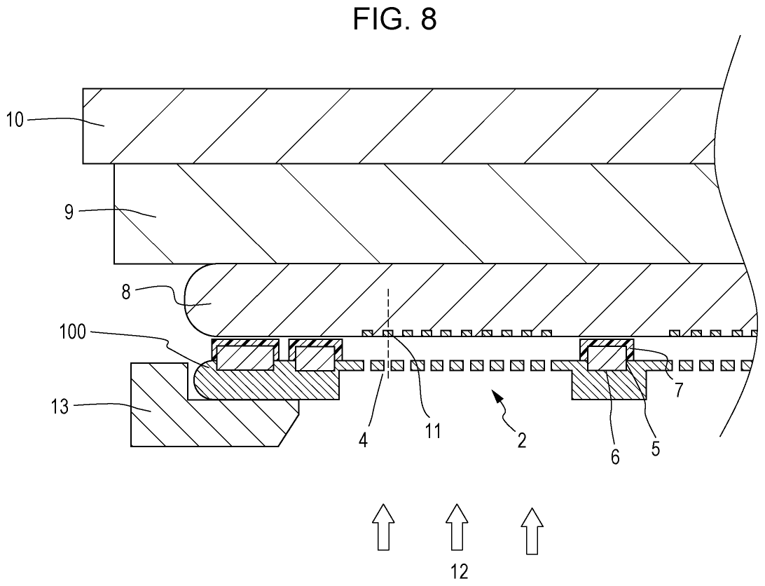

FIG. 8 is a schematic cross-sectional view illustrating how vapor deposition is performed using a vapor deposition mask according to a third embodiment. In the present embodiment, the depth of the recess 5 is equal to the thickness of the membrane regions 2. The description of other parts will be omitted, as they are the same as or similar to the first embodiment.

In the present embodiment, the magnetic layer 6 is thicker than the membrane regions 2. Therefore, the magnetic layer 6 has a volume large enough for the magnetic layer 6 to be attracted to the magnet 10.

### Method for Manufacturing Vapor Deposition Mask

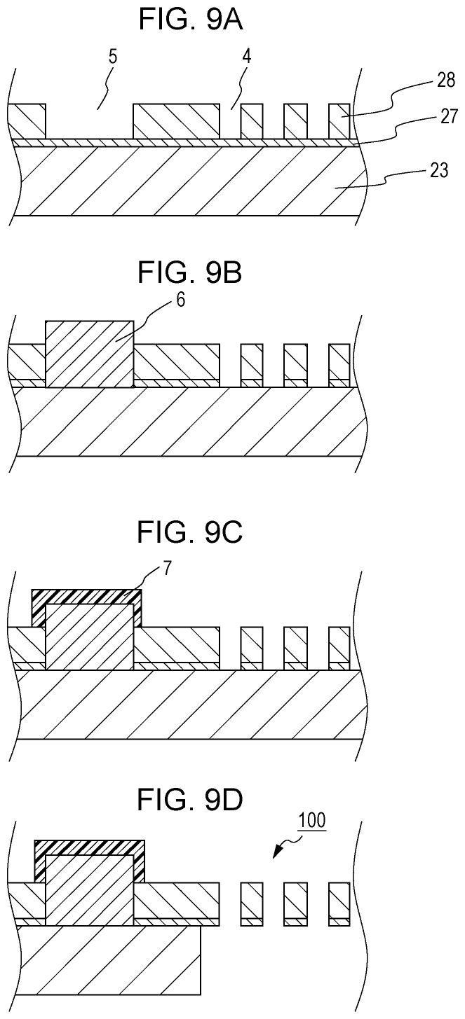

An example of a method for manufacturing the vapor deposition mask according to the present embodiment will now be described using FIG. 9A to FIG. 9D.

The silicon wafer 23 is used as a base material. First, as illustrated in FIG. 9A, a non-magnetic metal layer 28 is patterned on the silicon wafer 23. In the present example, an electroless nickel-phosphorus coating is patterned using a semi-additive process. Specifically, first, a palladium (Pd) thin film or the like is formed as a seed layer 27 on the surface of the silicon wafer 23. Then, a resist pattern (not illustrated) is formed in regions to be turned into the openings 4 and the recess 5, and subjected to electroless nickel-phosphorus plating. Here, the concentration of phosphorus in nickel is adjusted such that a film obtained by plating is a non-magnetic film. Then, the resist pattern (not illustrated) is removed to obtain the non-magnetic metal layer 28 having the pattern of the recess 5 and the regions to be turned into the openings 4. In the present example, the non-magnetic metal layer 28 is a main layer of the membrane region 2 and serves as a surface layer of the membrane region 2 on the same side as the surface of the beam region 3 having the magnetic layer 6 therein.

Next, as illustrated in FIG. 9B, the seed layer 27 in the regions to be turned into the openings 4 and at the bottom of the recess 5 is removed by wet etching or the like. Then, a magnetic metal-containing ink, such as a magnetite fine-particle ink, is applied by screen printing or the like to the recess 5, so as to pattern the magnetic layer 6 thicker than the membrane region 2.

Next, as illustrated in FIG. 9C, a resin, such as an acrylic resist (acrylic resin), is applied with a dispenser or the like to the magnetic layer 6 to form the low-hardness layer 7.

Then, the back side of the silicon wafer 23 is processed in a procedure similar to that illustrated in FIG. 4D to FIG. 5C of the first embodiment, so that the vapor deposition mask 100 illustrated in FIG. 9D can be obtained.

The vapor deposition mask of the third embodiment obtained as described above can be manufactured at lower cost, as it does not require excessive use of a vacuum process. Also, the vapor deposition mask of the third embodiment can be reliably attracted to the magnet and is resistant to plastic deformation and damage when attracted to the magnet or when brought into contact with the substrate to be subjected to vapor deposition. It is thus possible to achieve high precision and improved reliability of an organic electronic device, such as an organic light-emitting device.

### Manufacturing Method and Application of Organic Electronic Device

A method for manufacturing an organic electronic device according to the present embodiment includes, as illustrated in FIG. 2, placing the vapor deposition mask 100 of the present embodiment, with the surface thereof having the magnetic layer 6 therein facing the substrate 8; and vapor-depositing an organic material on the substrate 8. Examples of the organic electronic device according to the present embodiment include an organic light-emitting device, such as an organic EL display device.

An organic light-emitting device according to the present embodiment can be used as a component of a display apparatus or an illuminating apparatus. Other applications of the organic light-emitting device according to the present embodiment include an exposing source for an electrophotographic image forming apparatus, a backlight for a liquid crystal display apparatus, or a light-emitting device including a color filter and a white light source.

The display apparatus may be an image information processing apparatus that includes an image input unit configured to receive image information from an area charge-coupled device (CCD), a linear CCD, a memory card, or the like, and an information processing unit configured to process the received information, and is configured to display the received image on a display unit. The display apparatus may include the organic light-emitting device of the present embodiment. The organic light-emitting device may include a plurality of pixels, and at least one of the plurality of pixels may include an organic light-emitting element and an active element, such as a transistor, connected to the organic light-emitting element. Here, the substrate may be a semiconductor substrate, such as a silicon substrate, and the transistor may be a metal-oxide-semiconductor field-effect transistor (MOSFET) on the substrate. An image display apparatus includes an input unit configured to receive image information and a display unit configured to output an image, and the display unit includes a display device of the present embodiment.

A display unit included in an imaging device or an inkjet printer may have a touch panel function. A method for driving the touch panel function is not particularly limited, and may be of an infrared type, a capacitive type, a resistive film type, or an electromagnetic induction type. The display device may be used as a display unit of a multifunction printer.

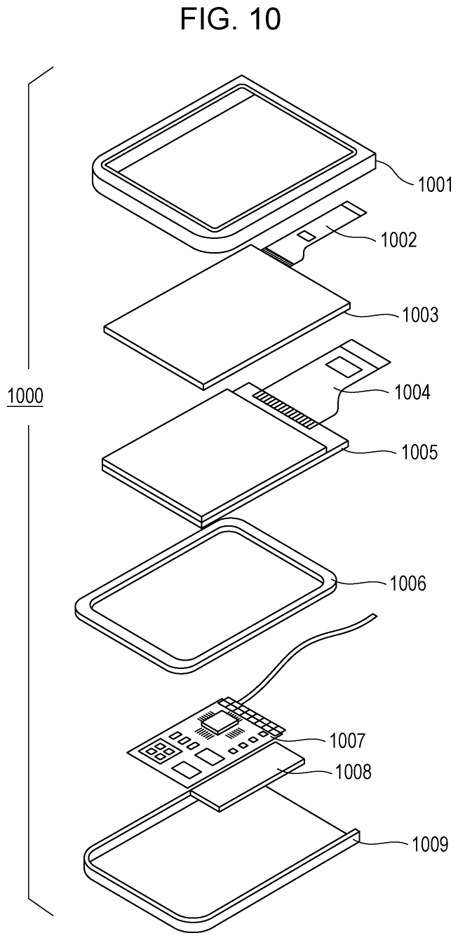

FIG. 10 schematically illustrates an example of the display device according to the present embodiment. A display device 1000 may include, between an upper cover 1001 and a lower cover 1009, a touch panel 1003, a display panel 1005, a frame 1006, a circuit board 1007, and a battery 1008. Flexible printed circuits (FPCs) 1002 and 1004 are connected to the touch panel 1003 and the display panel 1005, respectively. A transistor is printed on the circuit board 1007. The battery 1008 is optional when the display device is not a mobile device. Even when the display device is a mobile device, the battery 1008 may be provided in a different place.

The display device according to the present embodiment may include a color filter of red, green, and blue. The red, green, and blue of the color filter may be arranged in a delta configuration.

The display device according to the present embodiment may be used as a display unit of a mobile terminal. In this case, the display device may have both a display function and an operation function. Examples of the mobile terminal include mobile phones, such as smartphones, tablets, and head-mounted displays (HMDs).

The display device according to the present embodiment may be used as a display unit of an imaging device that includes an optical unit including a plurality of lenses and an imaging element configured to receive light passing through the optical unit. The imaging device may include a display unit configured to display information acquired by the imaging element. The display unit may be either one that is exposed to the outside of the imaging device, or one that is disposed inside the finder. The imaging device may be a digital camera or a digital video camera.

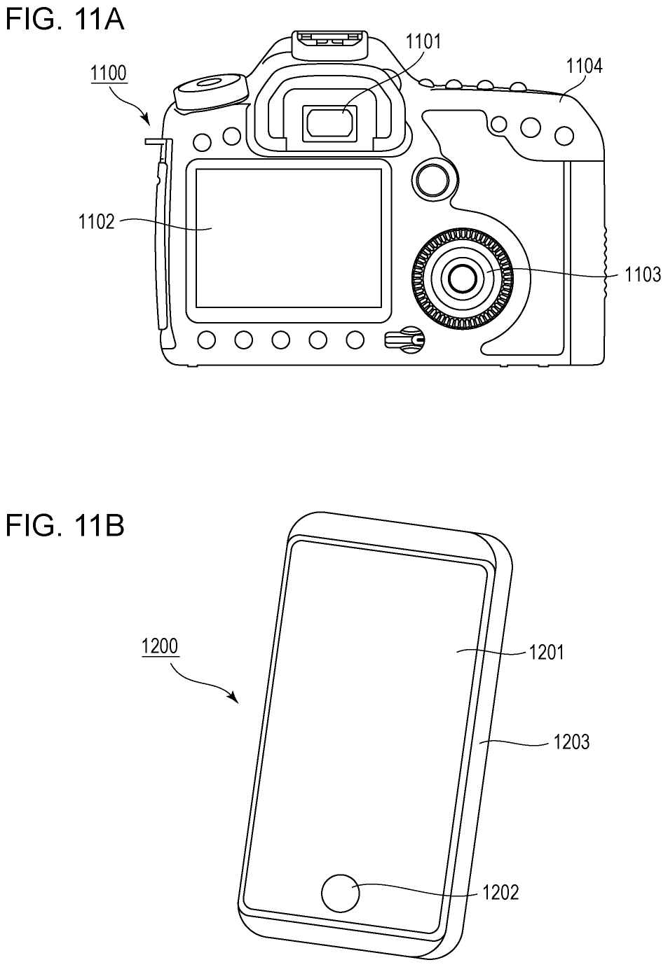

FIG. 11A schematically illustrates an example of an imaging device according to the present embodiment. An imaging device 1100 may include a viewfinder 1101, a back display 1102, an operation unit 1103, and a housing 1104. The viewfinder 1101 may include the display device according to the present embodiment. In this case, the display device may display not only an image to be captured, but also environmental information, imaging instructions, and the like. The environmental information may include the intensity of external light, the direction of external light, the moving speed of the subject, and the possibility that the subject will be blocked by an obstruction.

Since the timing suitable for capturing an image is limited, it is better to display information as quickly as possible. Therefore, a display apparatus using the organic light-emitting device of the present embodiment can be used. This is because the organic light-emitting device has a high response speed. The display apparatus using the organic light-emitting device can be used more preferably than a liquid crystal display apparatus that is required to have a high display speed.

The imaging device 1100 includes an optical unit (not illustrated). The optical unit includes a plurality of lenses and is configured to form an image on an imaging element housed in the housing 1104. Focus can be adjusted by adjusting the relative position of the plurality of lenses. This operation may be done automatically. The imaging device may also be referred to as a photoelectric conversion apparatus. Instead of sequentially capturing images, the photoelectric conversion apparatus may detect a difference from the preceding image, or may cut out part of an image constantly recorded, to capture an image.

FIG. 11B schematically illustrates an example of an electronic apparatus according to the present embodiment. An electronic apparatus 1200 includes a display unit 1201, an operation unit 1202, and a housing 1203. The housing 1203 may include a circuit, a printed board including the circuit, a battery, and a communicating unit. The display unit 1201 may include the organic light-emitting device according to the present embodiment. The operation unit 1202 may be a button or a reactive unit of touch panel type. The operation unit 1202 may be a biometric recognition unit configured to recognize a fingerprint for unlocking or the like. The electronic apparatus including the communicating unit may also be referred to as a communication apparatus. The electronic apparatus 1200 may include a lens and an imaging element to further provide a camera function. An image captured by the camera function is displayed on the display unit 1201. Examples of the electronic apparatus 1200 include smartphones and laptop computers.

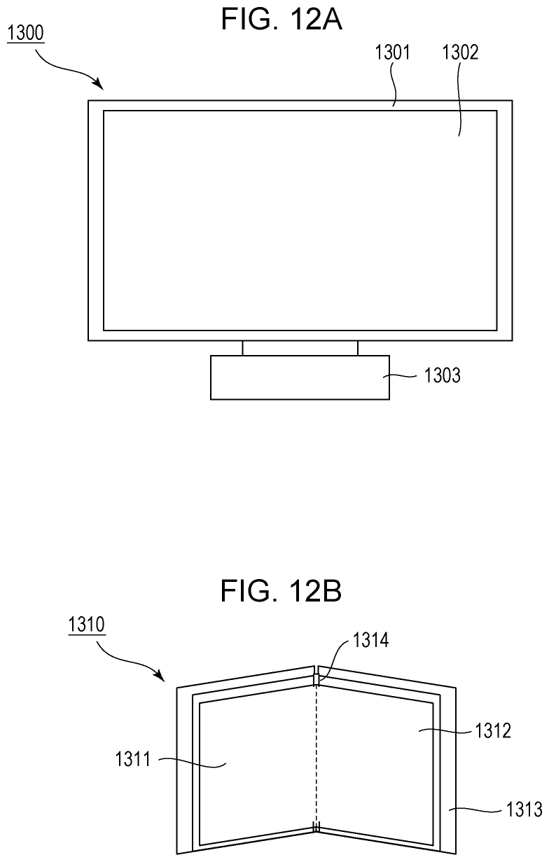

FIG. 12A and FIG. 12B each schematically illustrate an example of the display device according to the present embodiment. FIG. 12A illustrates a display device, such as a TV monitor or a PC monitor. A display device 1300 includes a frame 1301 and a display unit 1302. The display unit 1302 may include a light-emitting device according to the present embodiment. The display device 1300 includes a base 1303 configured to support the frame 1301 and the display unit 1302. The base 1303 is not limited to that illustrated in FIG. 12A. The lower side of the frame 1301 may also serve as a base. The frame 1301 and the display unit 1302 may be curved, and their radius of curvature may be greater than or equal to 5000 mm and less than or equal to 6000 mm.

FIG. 12B schematically illustrates another example of the display device according to the present embodiment. A display device 1310 illustrated in FIG. 12B is a so-called foldable display device configured to be capable of being folded up. The display device 1310 includes a first display unit 1311, a second display unit 1312, a housing 1313, and a folding point 1314. The first display unit 1311 and the second display unit 1312 may include the light-emitting device according to the present embodiment. The first display unit 1311 and the second display unit 1312 may be a single seamless display device. The first display unit 1311 and the second display unit 1312 may be separated at the folding point 1314. The first display unit 1311 and the second display unit 1312 may each display a different image, or may display a single image together.

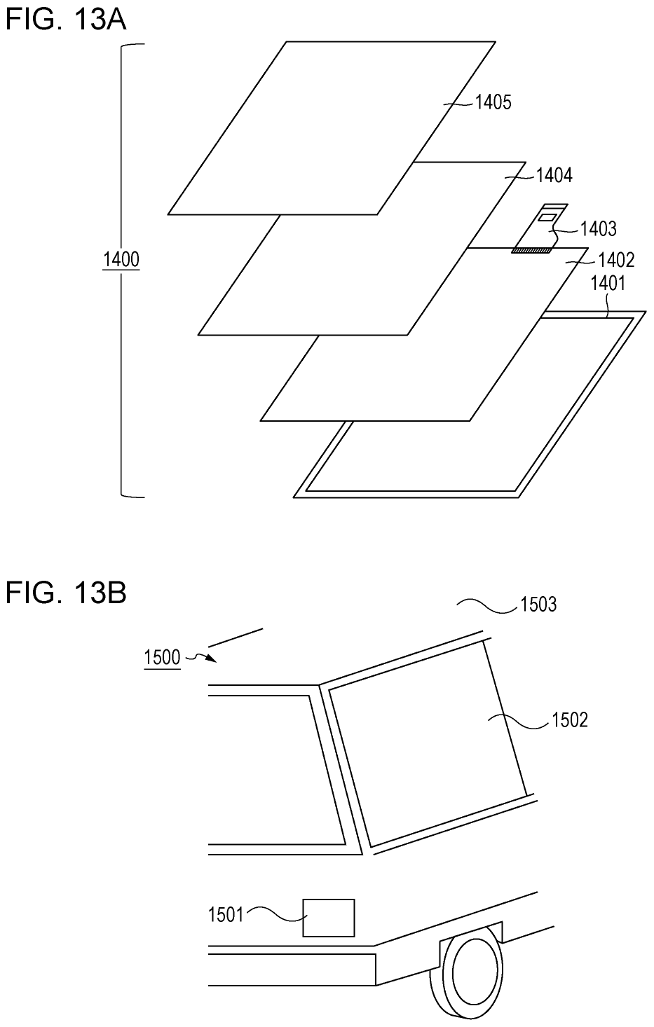

FIG. 13A schematically illustrates an example of an illuminating apparatus according to the present embodiment. An illuminating apparatus 1400 may include a housing 1401, a light source 1402, a circuit board 1403, an optical filter 1404 configured to transmit light emitted by the light source 1402, and a light diffuser 1405. The light source 1402 may include the organic light-emitting device according to the present embodiment. The optical filter 1404 may be a filter that improves color rendering properties of the light source 1402. The light diffuser 1405 can effectively diffuse light from the light source 1402 and distribute the light over a wide area for lighting up or the like. The optical filter 1404 and the light diffuser 1405 may be disposed on the light emerging side of the illumination, and may be provided with a cover on the outermost side as necessary.

The illuminating apparatus is, for example, an apparatus configured to illuminate a room. The illuminating apparatus may emit light of white, neutral white, or any other color selected from the range of blue to red colors. The illuminating apparatus may include a dimmer circuit configured to control the light or a toning circuit configured to control the color of emitted light. The illuminating apparatus may include the organic light-emitting device of the present embodiment and a power supply circuit connected thereto. The power supply circuit is a circuit configured to convert an alternating-current (AC) voltage into a direct-current (DC) voltage. The illuminating apparatus may include an inverter circuit. White has a color temperature of 4200 K, and neutral white has a color temperature of 5000 K. The illuminating apparatus may include a color filter.

The illuminating apparatus according to the present embodiment may include a heat dissipating unit. The heat dissipating unit is configured to release heat from inside to outside of the apparatus. For example, the heat dissipating unit may be made of metal with high specific heat, or liquid silicon.

FIG. 13B schematically illustrates a car that is an example of a moving body according to the present embodiment. The car includes a tail lamp that is an example of a lighting tool. A car 1500 may include tail lamps 1501 and may be configured to turn on the tail lamps 1501 when brakes are applied.

The tail lamps 1501 may each include the organic light-emitting device according to the present embodiment. The tail lamps 1501 may each include a protective member configured to protect the organic light-emitting device. The protective member may be made of any material that is transparent and has a certain degree of strength, but can be made of polycarbonate or the like. For example, the polycarbonate may be mixed with a furandicarboxylic acid derivative or an acrylonitrile derivative.

The car 1500 may include a car body 1503 and a window 1502 attached thereto. The window 1502 may be a transparent display unless it is intended for viewing the front or rear of the car 1500. The transparent display may include the organic light-emitting device according to the present embodiment. In this case, components of the organic light-emitting device, such as electrodes, are transparent.

The moving body according to the present embodiment may be, for example, a ship, an aircraft, or a drone. The moving body may include an airframe and a lighting tool included in the airframe. The lighting tool may emit light to indicate the location of the airframe. The lighting tool includes the organic light-emitting device according to the present embodiment.

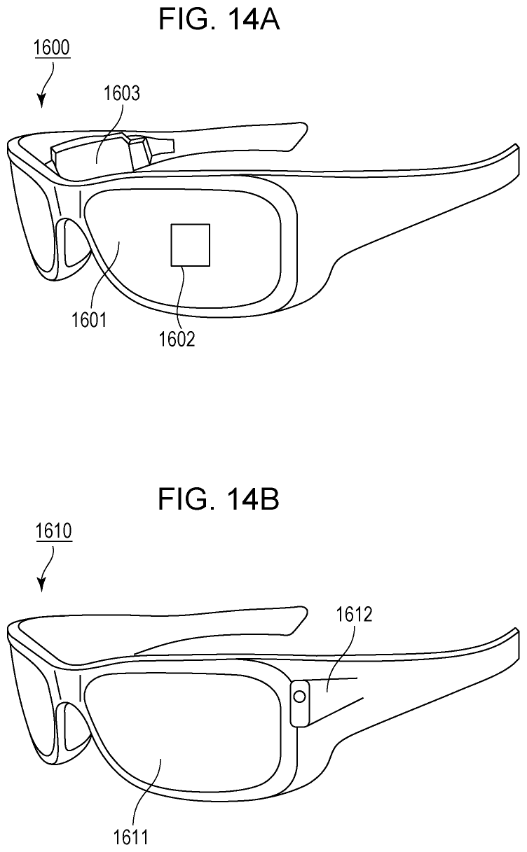

With reference to FIG. 14A and FIG. 14B, applications of the display device according to each of the aforementioned embodiments will now be described. The display device is applicable to systems that can be worn as wearable devices, such as smart glasses, HMDs, and smart contact lenses. An imaging and display apparatus used in such applications includes an imaging device capable of photoelectrically converting visible light and a display device capable of emitting visible light.

FIG. 14A schematically illustrates an example of a wearable device according to an embodiment of the present disclosure. Eyeglasses 1600 (smart glasses) according to an application will now be described using FIG. 14A. An imaging device 1602, such as a complementary metal-oxide-semiconductor (CMOS) sensor or a single-photon avalanche diode (SPAD), is disposed on the surface of a lens 1601 of the eyeglasses 1600. The display device according to any of the aforementioned embodiments is disposed on the back side of the lens 1601.

The eyeglasses 1600 further include a controller 1603. The controller 1603 serves as a power source configured to supply power to the imaging device 1602 and the display device. The controller 1603 is also configured to control the operation of the imaging device 1602 and the display device. The lens 1601 has an optical system for focusing light on the imaging device 1602.

FIG. 14B schematically illustrates another example of the wearable device according to the embodiment of the present disclosure. Eyeglasses 1610 (smart glasses) according to an application will now be described using FIG. 14B. The eyeglasses 1610 include a controller 1612, which includes an imaging device corresponding to the imaging device 1602 illustrated in FIG. 14A and a display device. A lens 1611 has an optical system for projecting light emitted from the imaging device and the display device included in the controller 1612, and an image is projected onto the lens 1611. The controller 1612 not only serves as a power source configured to supply power to the imaging device and the display device, but also controls the operation of the imaging device and the display device.

The controller 1612 may include a line-of-sight detector configured to detect a wearer's line of sight. The line of sight may be detected using infrared light. An infrared light-emitting unit emits infrared light toward an eyeball of the user who is gazing at a displayed image. The infrared light emitted is reflected from the eyeball and detected by an imaging unit including a light receiving element, so that a captured image of the eyeball is obtained. With a reducing unit configured to reduce light from the infrared light-emitting unit to a display unit in plan view, a degradation of image quality is reduced. From the captured image of the eyeball obtained by infrared imaging, a user's line of sight toward the displayed image is detected. Any known technique can be applied to line-of-sight detection using the captured image of the eyeball. For example, a line-of-sight detecting method based on a Purkinje image formed by reflection of irradiation light on the cornea can be used. More specifically, line-of-sight detection processing based on a pupil-corneal reflection method is performed. The user's line of sight is detected by using the pupil-corneal reflection method and calculating a line-of-sight vector representing the orientation (rotation angle) of the eyeball, on the basis of a pupil image included in the captured image of the eyeball and the Purkinje image.

A display device according to an embodiment of the present disclosure may include an imaging device including a light receiving element, and may control an image displayed on the display device on the basis of user's line-of-sight information from the imaging device. Specifically, on the basis of the line-of-sight information, the display device determines a first field-of-view region that the user is gazing at and a second field-of-view region outside the first field-of-view region. The first field-of-view region and the second field-of-view region may be either determined by a controller of the display device, or may be determined by and received from an external controller. In a display region of the display device, a display resolution in the first field-of-view region may be controlled to be higher than a display resolution in the second field-of-view region. That is, the resolution in the second field-of-view region may be lower than that in the first field-of-view region.

The display region includes a first display region and a second display region different from the first display region, and a high-priority region is determined from the first display region and the second display region on the basis of line-of-sight information. The first field-of-view region and the second field-of-view region may be either determined by the controller of the display device, or may be determined by and received from an external controller. A resolution in the high-priority region may be controlled to be higher than a resolution in a region other than the high-priority region. That is, a resolution in a lower-priority region may be set to be low.

The first field-of-view region and the high-priority region may be determined using artificial intelligence (AI). The AI may be a model configured to estimate, from an image of an eyeball, the angle of line of sight and the distance to an object at which the line of sight is directed, by using the image of the eyeball and the direction in which the eyeball in the image is actually looking as teaching data. The AI program may be included in the display device, the imaging device, or an external device. If included in the external device, the AI program is transmitted via communication to the display device.

For display control based on visual recognition detection, the display device is applicable to smart glasses that further include an imaging device configured to capture images of the outside. The smart glasses are capable of displaying captured outside information in real time.

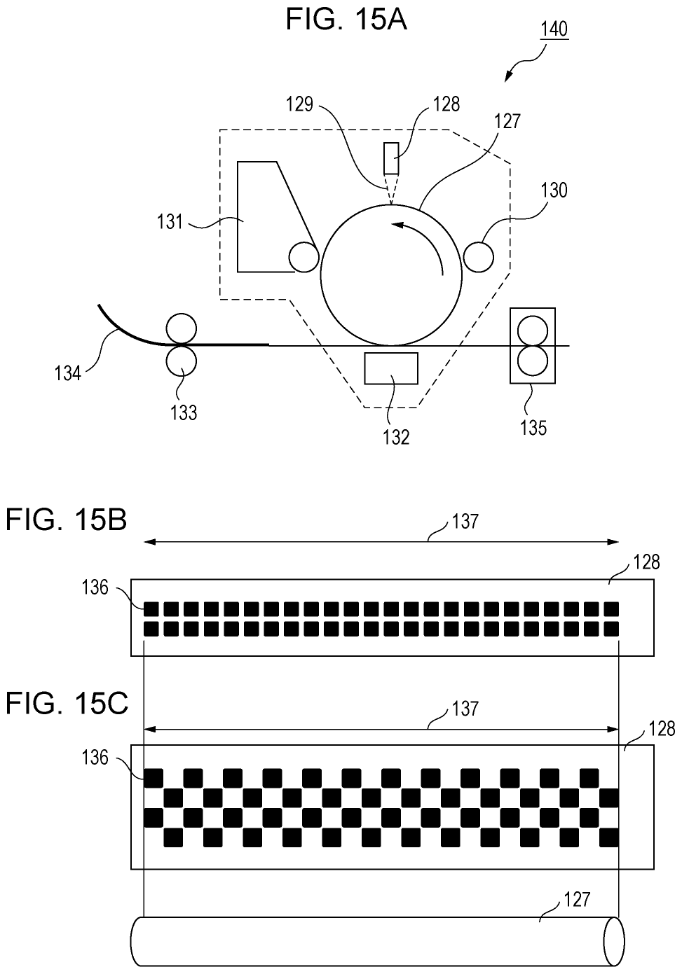

FIG. 15A schematically illustrates an example of an image forming apparatus according to an embodiment of the present disclosure. An image forming apparatus 140 is an electrophotographic image forming apparatus and includes a photosensitive member 127, an exposing source 128, a charging unit 130, a developing unit 131, a transfer unit 132, conveying rollers 133, and a fuser 135. Light 129 is emitted from the exposing source 128 to form an electrostatic latent image on the surface of the photosensitive member 127. The exposing source 128 includes the organic light-emitting device according to the present embodiment. The developing unit 131 includes toner or the like. The charging unit 130 is configured to charge the photosensitive member 127. The transfer unit 132 is configured to transfer a developed image onto a recording medium 134. The conveying rollers 133 are configured to convey the recording medium 134. For example, the recording medium 134 is paper. The fuser 135 is configured to fix an image formed on the recording medium 134.

FIG. 15B and FIG. 15C are diagrams each illustrating the exposing source 128. FIG. 15B and FIG. 15C each schematically illustrate how a plurality of light-emitting portions 136 are arranged on a long substrate. An arrow 137 represents a direction parallel to the axis of the photosensitive member 127 and indicates a column direction in which organic light-emitting elements are arranged. The column direction is the same as the direction of the axis on which the photosensitive member 127 rotates, and can also be referred to as a longitudinal direction of the photosensitive member 127. FIG. 15B illustrates the light-emitting portions 136 arranged along the longitudinal direction of the photosensitive member 127. Unlike the light-emitting portions 136 illustrated in FIG. 15B, the light-emitting portions 136 illustrated in FIG. 15C are alternately arranged in the column direction, in each of a first column and a second column. The first column and the second column are at different positions in the row direction. In the first column, the plurality of light-emitting portions 136 are arranged at intervals. In the second column, the light-emitting portions 136 are arranged at positions corresponding to spaces between adjacent ones of the light-emitting portions 136 in the first column. That is, the plurality of light-emitting portions 136 are arranged at intervals also in the row direction. The arrangement illustrated in FIG. 15C may also be referred to as a grid pattern, a staggered arrangement, or a checkered pattern.

As described above, with the organic light-emitting device according to the present embodiment, it is possible to provide stable display of good image quality even for a long time. Also, with the organic light-emitting device according to the present embodiment, it is possible to achieve both good visibility outdoors and power-saving display because of highly efficient and high-brightness light output.

### EXAMPLES

### Example 1

In the present example, the vapor deposition mask illustrated in FIG. 1A and FIG. 1B was manufactured in the procedure illustrated in FIG. 4A to FIG. 4D and FIG. 5A to FIG. 5C.

The SOI substrate 20 was used as a base material. In the present example, the device layer 14 of the SOI substrate 20 is a main material for forming each membrane region 2. Therefore, the thickness of the device layer 14 is set thicker than the BOX layer 15. The device layer 14 is a layer of single crystal silicon, which is high in Young's modulus, light in specific gravity, finely patterned easily, and thus is suitable as a material for forming the membrane region 2. The Young's modulus and the indentation hardness of the device layer 14, measured with a nanoindentation technique, were 135 GPa and 11.3 GPa, respectively.

First, as illustrated in FIG. 4A, a SiN film was formed as the stress adjusting layer 17 on the surface of the device layer 14 of the SOI substrate 20 by plasma-enhanced CVD to a thickness thinner than the device layer 14. The stress adjusting layer 17 is a surface layer of the membrane region 2 on the same side as the surface of the beam region 3 having the magnetic layer 6 therein. Under tensile stress applied by the stress adjusting layer 17, the membrane region 2 to be formed later can be easily maintained in a flat state. The membrane stress of the SiN film was a tensile stress of 150 MPa. The Young's modulus and the indentation hardness of the SiN film were 140 GPa and 7.5 GPa, respectively.

Next, as illustrated in FIG. 4B, the recess 5 and regions to be turned into the openings 4 were patterned by photolithography. Not only the stress adjusting layer 17 and the device layer 14, but also the BOX layer 15 and part of the handle layer 16, were etched by reactive ion etching (RIE) using a reactive gas.

After forming a seed layer (not illustrated) in the recess 5, the magnetic layer 6 made of nickel was formed, as illustrated in FIG. 4C, to a thickness 1.0 μm greater than the depth of the recess 5 by electroplating. Here, the indentation hardness of the magnetic layer 6 was 6.1 GPa. Then, electroless nickel and PTFE composite plating was performed on the magnetic layer 6 to form the low-hardness layer 7. The thickness and the indentation hardness of the low-hardness layer 7 were 1.0 μm and 2.6 GPa, respectively.

Next, as illustrated in FIG. 4D, a resist was air-sprayed over the entire surface of the SOI substrate 20 on the side of the device layer 14 to form the protective layer 18. Then, the conductive tape 19 was attached to the top of the protective layer 18 for more protection.

Next, the SOI substrate 20 to which the conductive tape 19 had been attached was subjected to processing on the side of the handle layer 16. First, as illustrated in FIG. 5A, a pattern of the resist 21 was formed, in a region to be turned into the beam region 3, by photolithography on the surface of the handle layer 16. Note that openings in the resist 21 become the membrane regions 2.

Next, as illustrated in FIG. 5B, the handle layer 16 was etched to the BOX layer 15. A Bosch process was used for etching.

Next, as illustrated in FIG. 5C, the conductive tape 19 was removed from the SOI substrate 20, and the resist 21 and the protective layer 18 were peeled off with an organic solvent to obtain the vapor deposition mask 100.

### Example 2

In the present example, the vapor deposition mask illustrated in FIG. 6 was manufactured in the procedure illustrated in FIG. 7A to FIG. 7D.

The silicon wafer 23 was used as a base material. First, as illustrated in FIG. 7A, the silicon oxide film 24, the silicon nitride film 25, and the silicon oxide film 26 were formed in sequence on the surface of the silicon wafer 23. The silicon oxide films 24 and 26 were formed by plasma-enhanced CVD, and the silicon nitride film 25 was formed by LP-CVD. In the present example, the silicon nitride film 25 becomes a main layer of the membrane region 2. Therefore, the thickness of the silicon nitride film 25 was set thicker than the total thickness of the silicon oxide films 24 and 26. The membrane stress of the silicon nitride film 25 was a tensile stress of 160 MPa. The Young's modulus and the indentation hardness of the silicon nitride film 25 were 230 GPa and 7.8 GPa, respectively.

Next, as illustrated in FIG. 7B, the recess 5 and regions to be turned into the openings 4 were patterned by photolithography. The silicon oxide films 24 and 26 and the silicon nitride film 25 were etched by reactive ion etching (RIE) using a reactive gas. Then, the silicon wafer 23 at the bottom of the openings 4 and the recess 5 was etched by the Bosch process.

After forming of a seed layer (not illustrated) in the recess 5, the magnetic layer 6 made of nickel was formed, as illustrated in FIG. 7C, to a thickness 0.5 μm less than the depth of the recess 5 by electroplating.

Then, the back side of the silicon wafer 23 was processed in a procedure similar to that illustrated in FIG. 4D to FIG. 5C of Example 1, so that the vapor deposition mask 100 illustrated in FIG. 7D was obtained.

### Example 3

In the present example, the vapor deposition mask illustrated in FIG. 8 was manufactured in the procedure illustrated in FIG. 9A to FIG. 9D.

The silicon wafer 23 was used as a base material. First, as illustrated in FIG. 9A, an electroless nickel-phosphorus plating was patterned as the non-magnetic metal layer 28 on the silicon wafer 23 using a semi-additive process. Specifically, first, a Pd thin film was formed as the seed layer 27 on the surface of the silicon wafer 23. Then, a resist pattern (not illustrated) was formed in regions to be turned into the openings 4 and the recess 5 and subjected to electroless nickel-phosphorus plating. Here, the concentration of phosphorus in nickel was set to 12 wt % such that a film obtained by plating was a non-magnetic film. Then, the resist pattern (not illustrated) was removed to obtain the non-magnetic metal layer 28 having the pattern of the recess 5 and the regions to be turned into the openings 4. In the present example, the non-magnetic metal layer 28 is a main layer of the membrane region 2 and serves as a surface layer of the membrane region 2 on the same side as the surface of the beam region 3 having the magnetic layer 6 therein. The membrane stress of the non-magnetic metal layer 28 was a tensile stress of 20 MPa. The Young's modulus and the indentation hardness of the non-magnetic metal layer 28 were 50 GPa and 5.5 GPa, respectively.

Next, as illustrated in FIG. 9B, the seed layer 27 in the regions to be turned into the openings 4 and at the bottom of the recess 5 was removed by wet etching. Then, a magnetite fine-particle ink was applied by screen printing to the recess 5, so as to pattern the magnetic layer 6. The thickness of the magnetic layer 6 was 5.0 μm greater than the thickness of the membrane region 2. The indentation hardness of the magnetic layer 6 was 4.5 GPa.

Next, as illustrated in FIG. 9C, an acrylic resist (acrylic resin) was applied with a dispenser to the magnetic layer 6 to form the low-hardness layer 7. The thickness and the indentation hardness of the low-hardness layer 7 were 2.0 μm and 1.9 GPa, respectively.

Then, the back side of the silicon wafer 23 was processed in a procedure similar to that illustrated in FIG. 4D to FIG. 5C of Example 1, so that the vapor deposition mask 100 illustrated in FIG. 9D was obtained.

The present disclosure can provide a vapor deposition mask that is resistant to plastic deformation and can be reliably attracted by magnetic force. It is thus possible to achieve high precision and improved reliability of an organic electronic device, such as an organic light-emitting device.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-028534 filed Feb. 28, 2024, which is hereby incorporated by reference herein in its entirety.

What is claimed is:

1. A vapor deposition mask comprising:
a base member made of a non-magnetic material,
wherein the base member includes a first region having a plurality of through holes and a second region thicker than the first region; and
the second region has a recess including a magnetic layer therein.

2. The vapor deposition mask according to claim 1, wherein the second region is disposed around the first region.

3. The vapor deposition mask according to claim 1, wherein the second region is disposed at an end portion of the base member.

4. The vapor deposition mask according to claim 1, wherein the recess is in a grid form.

5. The vapor deposition mask according to claim 1, wherein the recess is disposed along an outer periphery of the base member.

6. The vapor deposition mask according to claim 1, wherein the first region is disposed to be flush with a surface of the second region having the magnetic layer therein.

7. The vapor deposition mask according to claim 1, wherein the first region is made only of a non-magnetic material.

8. The vapor deposition mask according to claim 1, wherein a depth of the recess is greater than a thickness of the first region.

9. The vapor deposition mask according to claim 1, wherein a thickness of the magnetic layer is less than a depth of the recess.

10. The vapor deposition mask according to claim 1, wherein a thickness of the magnetic layer is greater than a depth of the recess.

11. The vapor deposition mask according to claim 1, wherein a main layer of the first region has a Young's modulus of greater than or equal to 50 GPa.

12. The vapor deposition mask according to claim 1, wherein a main layer of the first region is a non-magnetic metal layer.

13. The vapor deposition mask according to claim 1, wherein a main layer of the first region contains silicon.

14. The vapor deposition mask according to claim 1, further comprising a low-hardness layer on a surface of the magnetic layer,
wherein the low-hardness layer has a lower hardness than a surface of the magnetic layer and a surface of the first region on the same side as a surface of the second region having the magnetic layer therein.

15. The vapor deposition mask according to claim 14, wherein the low-hardness layer is made of an organic material.

16. The vapor deposition mask according to claim 14, wherein the low-hardness layer contains fluororesin.

17. A method for manufacturing an organic electronic device, the method comprising:
placing the vapor deposition mask according to claim 1, with a surface thereof having the magnetic layer therein facing a substrate to be subjected to vapor deposition; and
vapor-depositing an organic material on the substrate.
